(19) United States
(12) Patent Application Publication
(10) Pub. No.: US 2011/0108871 A1
(43) Pub. Date: May 12, 2011

(54) EDGE LED PACKAGE

(75) Inventor: CHIH-MING CHEN, Hukou (TW)

(73) Assignee: ADVANCED OPTOELECTRONIC TECHNOLOGY, INC., Hsinchu Hsien (TW)

(21) Appl. No.: 12/938,321

(22) Filed: Nov. 2, 2010

(30) Foreign Application Priority Data
Nov. 6, 2009 (CN) 200910212345.2

(51) Int. Cl. H01L 33/60

(52) U.S. Cl. 257/98; 257/E33.068

(57) ABSTRACT

An edge LED package includes a base, an LED die and a reflective cup. The LED die is located on a surface of the base. The reflective cup includes an inner sidewall surrounding the LED die. The inner sidewall inclines outward from the base to form an included angle from 140 to 150°. The depth of the reflective cup, measured vertically from top of the reflective cup to the bottom, is about 0.25 mm to 0.3 mm. The area ratio between the opening area of the reflective cup and the base area surrounded by the reflective cup is about 1.5 to 2.

### BACKGROUND

1. Technical Field

The present disclosure relates to an optical component, and particularly, to an edge light emitting diode (LED) package.

2. Description of Related Art

As shown in FIG. 1, an edge LED package 1 contains a lead 13, a housing 10 connected to the lead frame 13, an LED die 12 located on the lead frame 13 and surrounded by the housing 10, and an enclosure 15 covering the LED die 12 in the housing 10. An inner sidewall 11 of the housing 10 inclines outward from a base of the housing 10 to form an included angle θ1 from 90 to 110°. The depth D1 of the housing 10, measured vertically from top of the housing 10 to the base of the thereof, is about 0.6 mm. The inner sidewall 11 of the housing 10 refracts some light emitted from the LED die 12 to the light receiver 18. The length of the light path reduces efficiency of light emission.

Accordingly, it is desirable to provide an edge LED package which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a cross-section of a commonly used edge LED package.

FIG. 2 is a cross-section of an edge LED package according to a first embodiment of the present disclosure.

FIG. 3 is a top view of the edge LED package of FIG. 2.

FIG. 4 is an elevational view illustrating refraction of light at an inner sidewall of a reflective cup of the LED of FIG. 2.

FIG. 5 is a cross-section of an edge LED package according to a second embodiment of the present disclosure.

FIG. 6 illustrates light flux of the commonly used edge LED package and the edge LED package of the present disclosure.

FIG. 7 illustrates another light flux of the commonly used edge LED package and the edge LED package of the present disclosure.

### DETAILED DESCRIPTION

Embodiments of the disclosure will now be described in detail with reference to the accompanying drawings.

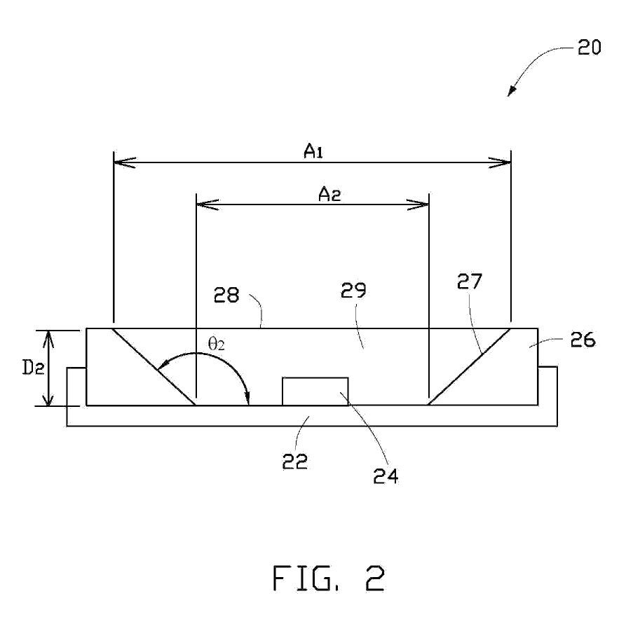

As shown in FIG. 2, an edge LED package 20 according to first embodiment includes a base 22, a reflective cup 26, an LED die 24 located on the base 22 and surrounded by the reflective cup 26, and an enclosure 29 covering the LED die 24 in the reflective cup 26.

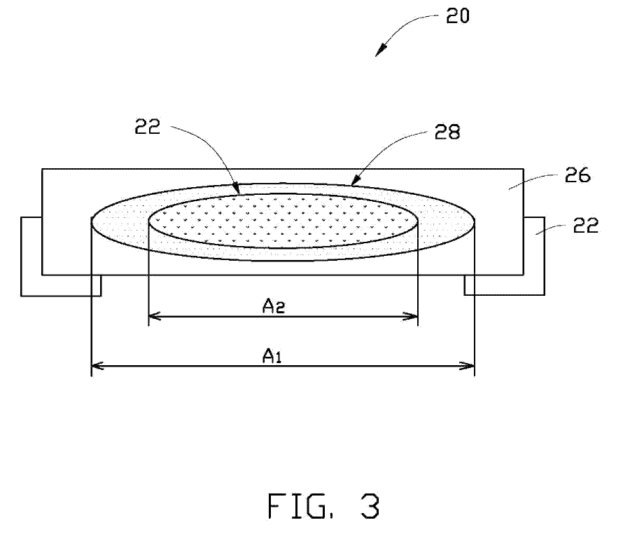

An inner sidewall 27 of the reflective cup 26 inclines outward from the base 22 to form an included angle θ2 from 140 to 150°. The depth D2 of the reflective cup 26, measured vertically from the top of the reflective cup 26 to the bottom of the reflective cup 26, is about 0.25 mm to 0.3 mm. Also referring to FIG. 3, the area ratio between the opening area A1 of the reflective cup 26 and the base area A2 surrounded by the reflective cup 26 is about 1.5 to 2. The opening area A1 and the base area A2 are substantially an ellipse. The reflective cup 26 is made of reflective material, such as white plastic, so light emitted toward the reflective cup 26 is reflected toward a light-emitting surface 28 of the enclosure 29. The enclosure 29 may be epoxy resin, silicone resin, or other electrically insulating transparent materials.

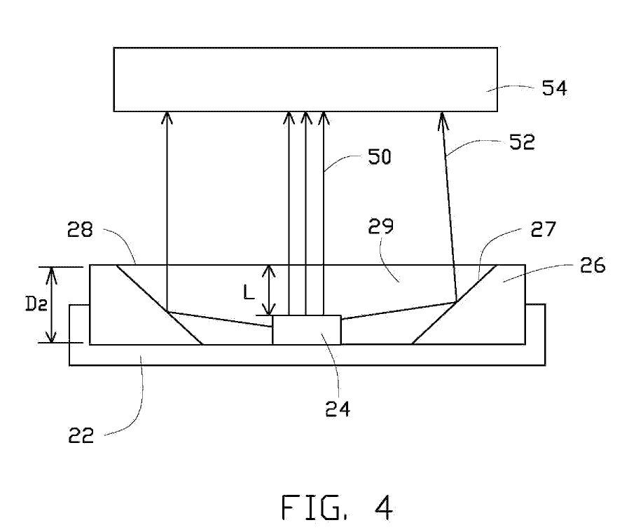

As shown in FIG. 4, the light-emitting distance L between the LED die 24 and the light-emitting surface 28 of the enclosure 29 is less than a commonly used package. Because the light-emitting distance L is shorter than a commonly used package, the included angle θ2 of the inner sidewall 27 is larger than a commonly used package, and the area ratio between the opening area A1 of the reflective cup 26 and the base area A2 surrounded by the reflective cup 26 is about 1.5 to 2. A light receiver 54 receives most light 50 emitted from the LED die 24. The inner sidewall 27 of the reflective cup 26 refracts a minimum of light 52 emitted from the LED die 24 to the light receiver 54. With the depth D2 of the reflective cup 26, included angle θ2 of the inner sidewall 27 and area ratio between the opening area A1 and the base area A2, maximum illumination can be achieved.

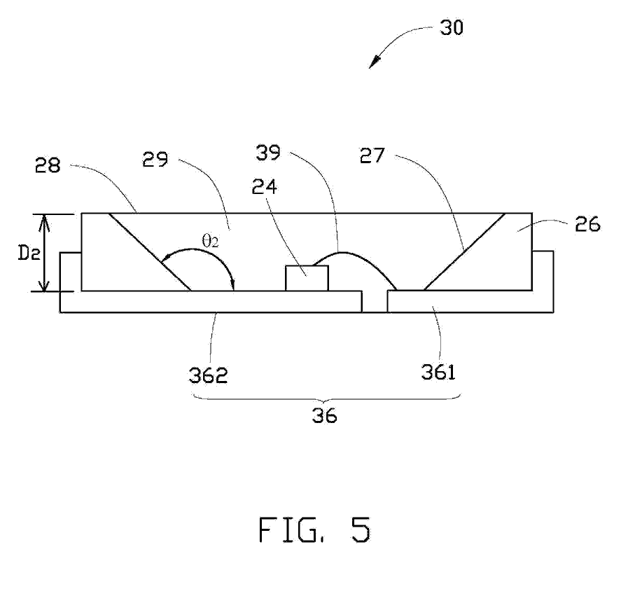

FIG. 5 illustrates an edge LED package 30 of a second embodiment of the disclosure, differing from the first embodiment only in that the base is a lead frame 36. The lead frame 36 includes first portion 361 and second portion 362. The LED die 24 is located on the second portion 362 of the lead frame 36 and electrically connected to the first portion 361 by a metal wire 39.

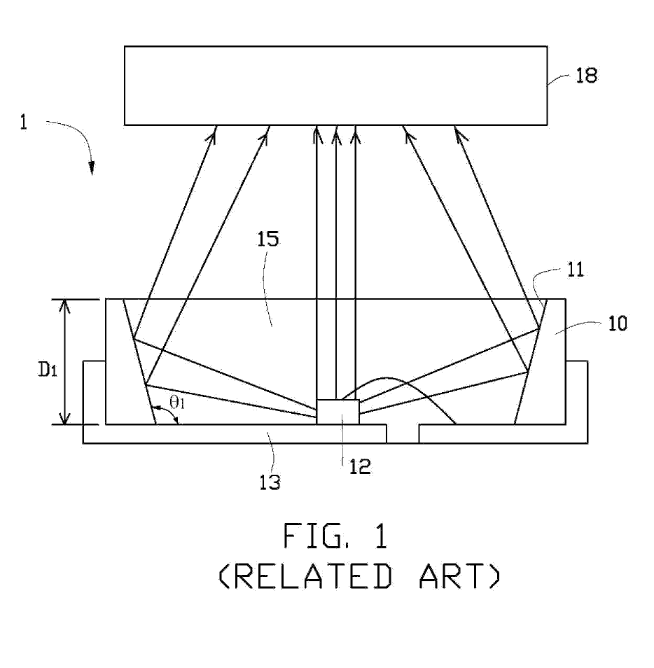

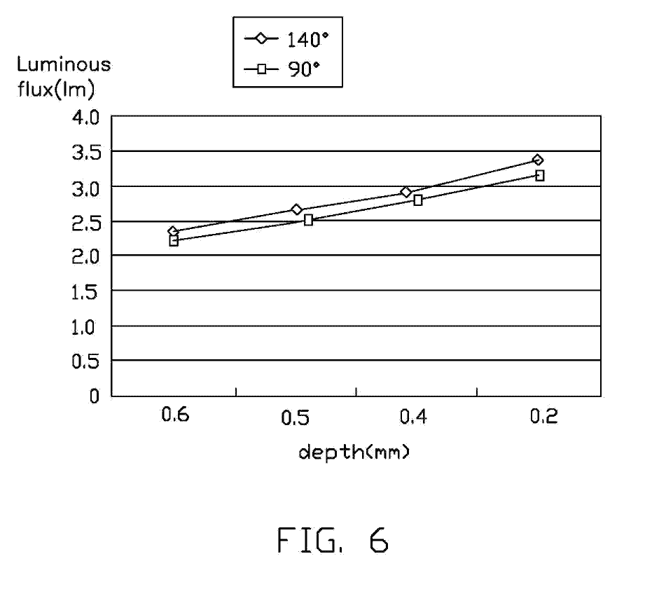

FIG. 6 shows luminous flux statistics of LED packages 20 of the first embodiment and a commonly used LED packages 1 of FIG. 1 respectively. The included angle θ1 of the housing 10 of a commonly used LED packages 1 is 90°. The included angle θ2 of the reflective cup 26 of the LED packages 20 of the first embodiment is 140°. The average luminous flux in the enclosure 29 is greater than that in a commonly used package 1 due to the included angle θ2 of the reflective cup 26. Accordingly, the luminous intensity of the present disclosure can be increased in comparison with a commonly used package at the same depth conditions.

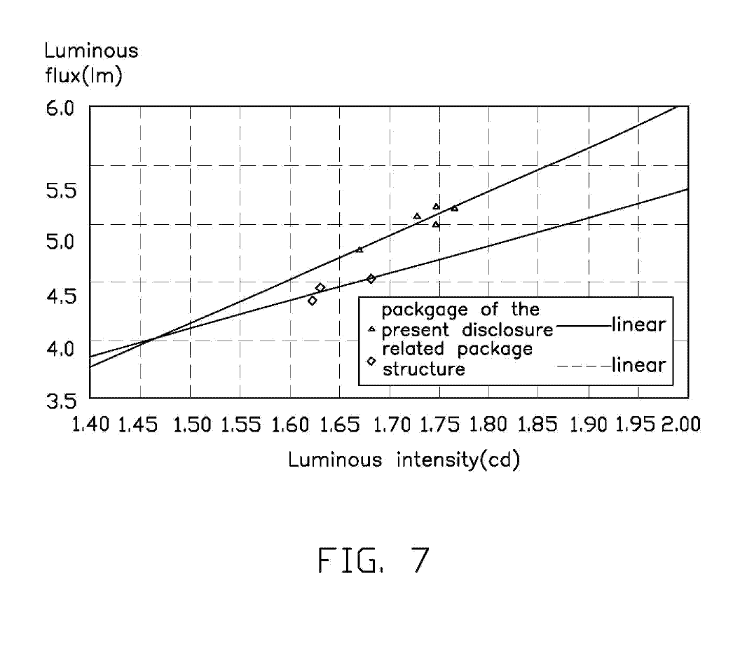

FIG. 7 shows other luminous flux statistics of LED package 20 of the first embodiment and a commonly used LED package 1 of FIG. 1 respectively. The included angle θ1 of the housing 10 of a commonly used LED package 1 is 90°. The depth D1 of the housing 10 of a commonly used LED package 1 is 0.3 mm. The included angle θ2 of the reflective cup 26 of the LED packages 20 of the first embodiment is 140°. The depth D2 of the reflective cup 26 of the LED packages 20 is 0.6 mm. The luminous flux of the present disclosure can be increased in comparison with a commonly used package at the same luminous intensity conditions.

It is to be understood, however, that even though numerous characteristics and advantages of the present embodiments have been set fourth in the foregoing description, together with details of the package and functions of the embodiments, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. An edge light emitting diode (LED) package, comprising:
a base;
an LED die located on a surface of the base; and
a reflective cup connecting to the base and surrounding the LED die, the reflective cup comprising an inner sidewall inclined outward from the base to form an included angle from 140 to 150°, and the depth of the reflective cup measured vertically from top of the reflective cup to the bottom being about 0.25 mm to 0.3 mm.

2. The edge LED package of claim 1, further comprising an enclosure filling the reflective cup and covering the LED die.

3. The edge LED package of claim 2, wherein the enclosure is made of epoxy resin, silicone resin, or other electrically insulating transparent materials.

4. The edge LED package of claim 1, wherein the opening area and the base area are ellipses.

5. The edge LED package of claim 1, wherein the reflective cup is made of reflective material.

6. The edge LED package of claim 1, wherein the area ratio between an opening area of the reflective cup and a base area surrounded by the reflective cup being about 1.5 to 2.

7. An edge light emitting diode (LED) package, comprising:
a base;
an LED die located on a surface of the base; and
a reflective cup connecting to the base and surrounding the LED die, the reflective cup comprising an inner sidewall, the depth of the reflective cup measured vertically from top of the reflective cup to the bottom being about 0.25 mm to 0.3 mm, the area ratio between an opening area of the reflective cup and a base area surrounded by the reflective cup being about 1.5 to 2.

8. The edge LED package of claim 7, further comprising an enclosure filling the reflective cup and covering the LED die.

9. The edge LED package of claim 8, wherein the enclosure is made of epoxy resin, silicone resin, or other electrically insulating transparent materials.

10. The edge LED package of claim 7, wherein the opening area and the base area are ellipses.

11. The edge LED package of claim 7, wherein the reflective cup is made of reflective material.

12. The edge LED package of claim 7, wherein the inner sidewall inclines outward from the base to form an included angle from 140 to 150°.

13. An edge light emitting diode (LED) package, comprising:
a base;
an LED die located on a surface of the base; and
a reflective cup connecting to the base and surrounding the LED die, the reflective cup comprising an inner sidewall inclined outward from the base to form an included angle from 140 to 150°, and the area ratio between an opening area of the reflective cup and a base area surrounded by the reflective cup being about 1.5 to 2.

14. The edge LED package of claim 13, further comprising an enclosure filling the reflective cup and covering the LED die.

15. The edge LED package of claim 14, wherein the enclosure is made of epoxy resin, silicone resin, or other electrically insulating transparent materials.

16. The edge LED package of claim 13, wherein the opening area and the base area are ellipses.

17. The edge LED package of claim 13, wherein the reflective cup is made of reflective material.

18. The edge LED package of claim 13, wherein the depth of the reflective cup measured vertically from top of the reflective cup to the bottom is about 0.25 mm to 0.3 mm.
